(19) United States
(12) Patent Application Publication
(10) Pub. No.: US 2008/0257595 A1
(43) Pub. Date: Oct. 23, 2008

(54) Packaging substrate and method for manufacturing the same

(75) Inventor: Wen-Hung Hu, Hsinchu (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/081,423

(22) Filed: Apr. 16, 2008

(30) Foreign Application Priority Data
Apr. 18, 2007 (TW) 096113596

(51) Int. Cl. H01R 12/04; H05K 3/10

(52) U.S. Cl. 174/261; 29/846

(57) ABSTRACT

The present invention relates to a packaging substrate and a method for manufacturing the same. The packaging substrate includes: a substrate body, having a plurality of conductive pads on the surface thereof, wherein the top surfaces of the conductive pads have a concave each; a solder mask, disposed on the surface of the substrate body and having a plurality of openings to correspondingly expose the concaves of the conductive pads each; and a plurality of metal bumps, disposed correspondingly in the openings of the solder mask and over the concaves of the conductive pads. The present invention increases the joint surface area between the metal bumps and the conductive pads so as to inhibit the joint crack and improve the reliability of the conductive structure of the packaging substrate.

### BACKGROUND OF THE INVENTION

1. Field of the Invention

The present invention relates to a packaging substrate and a method for manufacturing the same and, more particularly, to a packaging substrate that can increase the joint surface area between conductive pads and metal bumps and a method for manufacturing the same.

2. Description of Related Art

As the electronic industry develops rapidly, research accordingly moves towards electronic devices with multifunction and high efficiency. Hence, circuit boards with many active and passive components and circuit connections have advanced from being single-layered boards to multiple-layered boards so that the packaging requirements such as integration and miniaturization in semiconductor packaging can be met. Furthermore, interlayer connection technique is also applied in this field to expand circuit layout space in a limited circuit board and to meet the demand of the application of high-density integrated circuits.

In a general process for manufacturing semiconductor devices, semiconductor chip carriers such as substrates or lead frames suitable for semiconductor devices are first provided by manufacturers. Then, the semiconductor chip carriers are processed by semiconductor chip attachment, wire bonding, encapsulating, implanting solder ball etc. for assembling semiconductor devices. In general, a conventional semiconductor package structure is made such that a semiconductor chip is mounted by its back surface on the top surface of the substrate, then the package structure is finished through wire bonding, or a semiconductor chip is mounted by the active surface thereof on the top surface of the substrate, thereby finishing a flip-chip package structure, followed by placing solder balls on the back surface of the substrate to provide electrical connections for an electronic device like a printed circuit board.

In the aforementioned flip chip package, when the line width and the space width of the semiconductor packaging substrate are reduced, the decrease of joint surface area causes the reduction of joint strength. Thereby, the reduced joint strength cannot always bear the stress between the chip and the substrate, and the matter of joint crack becomes serious.

With reference to FIGS. 1A and 1B, there is shown a conventional packaging substrate. As shown in FIG. 1A, the conventional packaging substrate comprises: a substrate body 11 having a plurality of conductive pads 12 on the surface thereof; a solder mask 13 disposed on the surface of the substrate body 11 and having a plurality of openings to correspondingly expose the conductive pads 12; and metal bumps 14 formed correspondingly in the openings. Hereafter, the process for forming the metal bumps 14 is illustrated. First, a seed layer (not shown in the figures) is formed on the surface of the substrate body 11, and then a patterned photoresist layer (not shown in the figures) having openings to correspondingly expose the conductive pads 12 is formed. Subsequently, metal bumps 14 are formed correspondingly in the openings by electroplating. Herein, the material of the metal bumps 14 can be copper or other metals. Finally, the photoresist layer and the seed layer covered thereby are removed. In addition, as shown in FIG. 1B, solder bumps 15 can be formed on the surfaces of the metal bumps 14 to electrically connect with a chip (not shown in the figures) by reflow soldering.

Although the aforementioned structure can be used to electrically connect with a chip, it falls short of demand for package structure with high-density integration and miniaturization, owing to the trend of reducing the critical dimension (such as minimum line width), such that the reduced joint surface area between the metal bumps 14 and the conductive pads 12 makes the joint strength fail to bear the stress between the chip and the substrate, thereby the matter of joint crack frequently occurs and the reliability requirement of the product cannot be met.

### SUMMARY OF THE INVENTION

In view of the above-mentioned disadvantages, the object of the present invention is to provide a packaging substrate to increase the joint surface area between metal bumps and conductive pads and further inhibit the joint crack generally occurring in a conventional packaging substrate. Accordingly, the reliability of the packaging substrate can be enhanced, and the packaging substrate can be employed for meeting the trend of reducing the critical dimension of circuits of the substrate.

To achieve the aforementioned and other objects, the present invention provides a packaging substrate comprising: a substrate body, having a plurality of conductive pads on the surface thereof, wherein the top surfaces of the conductive pads have a concave each; a solder mask, disposed on the surface of the substrate body and having a plurality of openings to correspondingly expose the concaves of the conductive pads; and a plurality of metal bumps, disposed correspondingly in the openings of the solder mask and over the concaves of the conductive pads. Herein, the metal bumps can be higher than the surface of the solder mask, and the parts of metal bumps higher than the surface of the solder mask can have a width bigger than the size of the openings of the solder mask.

The packaging substrate of the present invention can further comprise solder bumps correspondingly disposed over the surfaces of the metal bumps.

The aforementioned packaging substrate of the present invention can further comprise a metal connective layer disposed between the metal bumps and the solder bumps.

The present invention further provides a method for manufacturing a packaging substrate, for example but not limited thereto, comprising: providing a substrate body, which has a plurality of conductive pads on the surface thereof; forming a solder mask on the surface of the substrate body, and forming a plurality of openings in the solder mask to correspondingly expose the conductive pads; micro-etching the surfaces of the conductive pads to form concaves; and forming metal bumps by electroplating correspondingly in the openings of the solder mask.

The aforementioned method can further comprise a step for forming solder bumps over the surfaces of the metal bumps.

The aforementioned method can further comprise a step for forming a metal connective layer on the surfaces of the metal bumps before forming the solder bumps.

In the present invention, the metal bumps are formed over the concaves of the conductive pads to increase the joint surface area and further enhance the connection between the metal bumps and the conductive pads, so that the joint crack generally occurring in a conventional packaging substrate can be inhibited so as to enhance the reliability of the packaging substrate. Accordingly, the packaging substrate of the present invention can be employed for meeting the trend of reducing the critical dimension of circuits of the substrate.

Other objects, advantages, and novel features of the invention will become more apparent from the following detailed description when taken in conjunction with the accompanying drawings.

### BRIEF DESCRIPTION OF THE DRAWINGS

FIGS. 1A and 1B show cross-sectional views of conventional packaging substrate; and

FIGS. 2A to 2G show a process for manufacturing a packaging substrate of a preferred embodiment of the present invention.

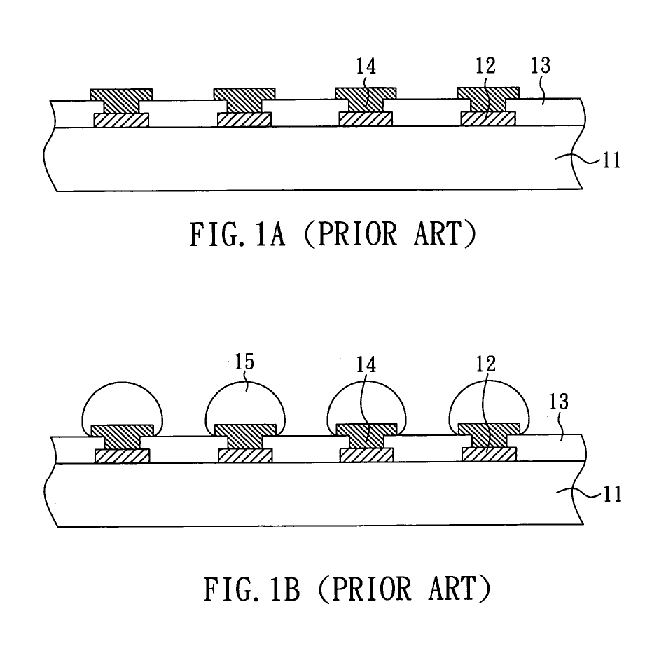

### DETAILED DESCRIPTION OF THE PREFERRED EMBODIMENT

Because the specific embodiments illustrate the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### Method Embodiment

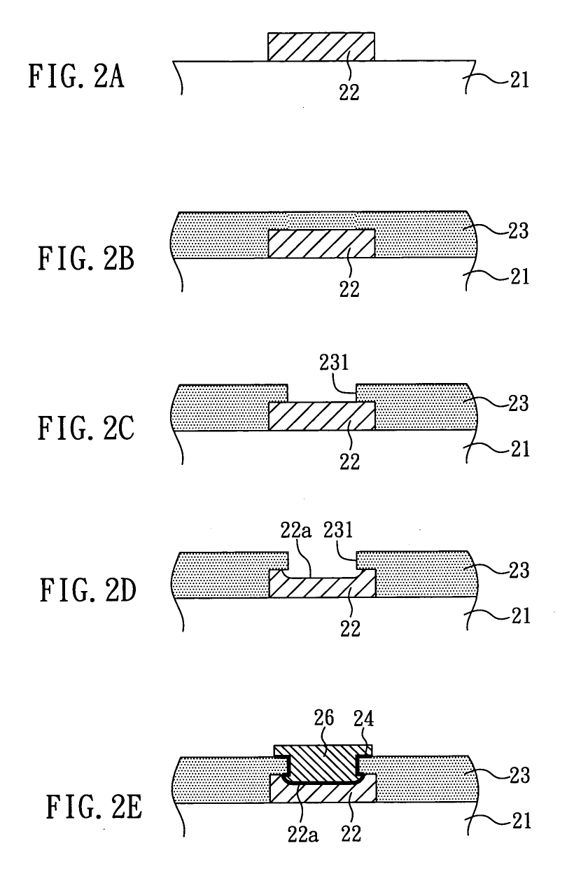

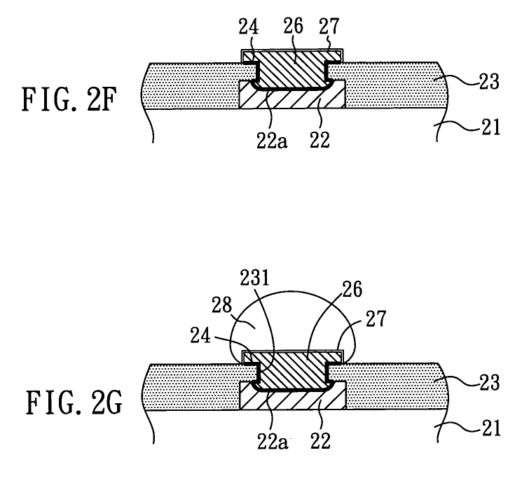

With reference to FIG. 2A, a substrate body 21 is first provided, which has a plurality of conductive pads 22 on the surface thereof. Herein, the material of the conductive pads 22 can be selected from the group consisting of copper, tin, nickel, chromium, titanium, copper-chromium alloy and tin-lead alloy. In the present embodiment, the material of the conductive pads 22 is copper. With reference to FIGS. 2B and 2C, a solder mask 23 is formed on the surface of the substrate body 21, and a plurality of openings 231 are formed in the solder mask 23 to correspondingly expose the conductive pads 22. With reference to FIG. 2D, after the openings 231 of the solder mask 23 are formed, concaves 22a are formed on the surfaces of the conductive pads 22 by a micro-etching process. Herein, the micro-etching process is a wet etching process. Subsequently, as shown in FIG. 2E, metal bumps 26 are formed correspondingly in the openings 231 (as shown in FIG. 2D) of the solder mask 23 by electroplating. As shown in FIG. 2E, the metal bumps are formed over the concaves 22a of the conductive pads 22. The material of the metal bumps 22 can be selected from the group consisting of copper, tin, nickel, chromium, titanium, copper-chromium alloy and tin-lead alloy. In the present embodiment, the material of the metal bumps is copper.

In the above-mentioned method, the process for forming the metal bumps 26 comprises the following steps. First, a seed layer 24 is formed on the surface of the substrate body 21 to function as a current conduction path needed for a following electroplating process. Then, a photoresist layer (not shown in the figures) is formed on the surface of the seed layer 24, and a plurality of openings (not shown in the figures) are formed in the photoresist layer. Herein, the openings of the photoresist layer correspond to the openings of the solder mask 23. Subsequently, metal bumps 26 are formed in the openings of the photoresist layer and the openings of the solder mask 23 and over the concaves 22a of the conductive pads 22. Finally, the photoresist layer and the seed layer 24 covered thereby are removed. Herein, the material of the seed layer 24 can be selected from the group consisting of copper, tin, nickel, chromium, titanium, copper-chromium alloy and tin-lead alloy, and the seed layer 24 can be formed by physical deposition (such as sputtering or evaporation) or chemical deposition (such as electroless plating). In the present embodiment, the material of the seed layer 24 is copper, and the seed layer 24 is formed by electroless plating.

Subsequently, as shown in FIG. 2F, a metal connective layer 27 is formed on the surface of the metal bumps 26 by physical deposition (such as sputtering or evaporation) or chemical deposition (such as electroless plating). The material of the metal connective layer 27 can be selected from the group consisting of tin, silver, nickel, gold, chromium/titanium, nickel/gold, nickel/palladium and nickel/palladium/gold. In the present embodiment, an electroless plating process is performed to deposit a nickel layer on the surfaces of the metal bumps 26 and then a gold layer on the surface of the nickel layer.

Finally, as shown in FIG. 2G, solder bumps 28 are formed by electroplating or printing.

### Structure Embodiment

As shown in FIG. 2G, the packaging substrate of the present embodiment comprises: a substrate body 21, having a plurality of conductive pads 22 on the surface thereof, wherein the top surfaces of the conductive pads 22 have a concave 22a each; a solder mask 23, disposed on the surface of the substrate body 21 and having a plurality of openings 231 to correspondingly expose the concaves 22a of the conductive pads 22; and a plurality of metal bumps 26, disposed correspondingly in the openings 231 of the solder mask 23 and over the concaves 22a of the conductive pads 22. Herein, the metal bumps 26 are higher than the surface of the solder mask 23, and the parts of metal bumps 26 higher than the surface of the solder mask 23 have a width bigger than the size of the openings 231 of the solder mask 23. Also, the parts of metal bumps 26 higher than the surface of the solder mask 23 can have a width equal to the size of the openings 231 of the solder mask 23 (not shown in the figures).

In the above-illustrated structure, the packaging substrate further comprises solder bumps 28 correspondingly disposed over the surfaces of the metal bumps 26.

In the above-illustrated structure, the packaging substrate further comprises a metal connective layer 27 disposed between the metal bumps 26 and the solder bumps 28.

In the above-illustrated structure, the material of the metal connective layer 27 is selected from the group consisting of tin, silver, nickel, gold, chromium/titanium, nickel/gold, nickel/palladium, and nickel/palladium/gold.

In the above-illustrated structure, the material of the metal bumps 26 is selected from the group consisting of copper, tin, nickel, chromium, titanium, copper-chromium alloy, and tin-lead alloy.

As above-mentioned, in the packaging substrate and the method for manufacturing the same, the metal bumps are formed over the concaves of the conductive pads to increase the joint surface area and further enhance the connection between the metal bumps and the conductive pads, so that the joint crack between the metal bumps and the conductive pads can be inhibited so as to enhance the reliability of the packaging substrate. Accordingly, the packaging substrate of the present invention can be employed for meeting the trend of reducing the critical dimension of circuits of the substrate.

Although the present invention has been explained in relation to its preferred embodiment, it is to be understood that many other possible modifications and variations can be made without departing from the scope of the invention as hereinafter claimed.

What is claimed is:

1. A packaging substrate, comprising:
a substrate body, having a plurality of conductive pads on the surface thereof, wherein the top surfaces of the conductive pads have a concave each;
a solder mask, disposed on the surface of the substrate body and having a plurality of openings to correspondingly expose the concaves of the conductive pads; and
a plurality of metal bumps, correspondingly disposed in the openings of the solder mask and over the concaves of the conductive pads.

2. The packaging substrate as claimed in claim 1, wherein the metal bumps are higher than the surface of the solder mask, and the parts of metal bumps higher than the surface of the solder mask have a width bigger than the size of the openings of the solder mask.

3. The packaging substrate as claimed in claim 1, further comprising solder bumps correspondingly disposed over the surfaces of the metal bumps.

4. The packaging substrate as claimed in claim 3, further comprising a metal connective layer disposed between the metal bumps and the solder bumps.

5. The packaging substrate as claimed in claim 4, wherein the material of the metal connective layer is selected from the group consisting of tin, silver, nickel, gold, chromium/titanium, nickel/gold, nickel/palladium, and nickel/palladium/gold.

6. The packaging substrate as claimed in claim 1, wherein the material of the metal bumps is selected from the group consisting of copper, tin, nickel, chromium, titanium, copper-chromium alloy, and tin-lead alloy.

7. A method for manufacturing a packaging substrate, comprising:
providing a substrate body, which has a plurality of conductive pads on the surface thereof;
forming a solder mask on the surface of the substrate body, and forming a plurality of openings in the solder mask to correspondingly expose the conductive pads;
micro-etching the surfaces of the conductive pads to form concaves; and
forming metal bumps by electroplating correspondingly in the openings of the solder mask.

8. The method as claimed in claim 7, wherein the metal bumps are formed by a process comprising:
forming a seed layer on the surface of the substrate body;
forming a photoresist layer on the surface of the seed layer and forming a plurality of openings in the photoresist layer, wherein the openings of the photoresist layer correspond to the openings of the solder mask;
forming metal bumps by electroplating correspondingly in the openings of the photoresist layer and the openings of the solder mask and over the concaves of the conductive pads exposed therein; and
removing the photoresist layer and the seed layer covered thereby.

9. The method as claimed in claim 7, further comprising forming solder bumps correspondingly over the surfaces of the metal bumps each.

10. The method as claimed in claim 9, wherein the solder bumps are formed by electroplating or printing.

11. The method as claimed in claim 9, further comprising forming a metal connective layer correspondingly on the surfaces of the metal bumps before forming the solder bumps.

12. The method as claimed in claim 11, wherein the metal connective layer is formed by physical deposition or chemical deposition.
